(19) United States
(12) Patent Application Publication
(10) Pub. No.: US 2022/0006006 A1
(43) Pub. Date: Jan. 6, 2022

(54) SPIN CURRENT MAGNETIZATION REVERSAL-TYPE MAGNETORESISTIVE EFFECT ELEMENT AND METHOD FOR PRODUCING SPIN CURRENT MAGNETIZATION REVERSAL-TYPE MAGNETORESISTIVE EFFECT ELEMENT

(71) Applicant: TDK CORPORATION, Tokyo (JP)

(72) Inventors: Eiji KOMURA, Tokyo (JP); Tomoyuki SASAKI, Tokyo (JP)

(73) Assignee: TDK CORPORATION, Tokyo (JP)

(21) Appl. No.: 17/478,475

(22) Filed: Sep. 17, 2021

Related U.S. Application Data
(63) Continuation-in-part of application No. 15/778,174, filed on May 22, 2018.

(30) Foreign Application Priority Data
Nov. 27, 2015 (JP) 2015-232334
Mar. 16, 2016 (JP) 2016-053072
Mar. 18, 2016 (JP) 2016-056058
Oct. 27, 2016 (JP) 2016-210531
Oct. 27, 2016 (JP) 2016-210533

(51) Int. Cl. H01L 43/08; H01L 43/14; H01L 43/10; H01L 43/04; H01L 27/22; G11C 11/16; G01R 33/09

(52) U.S. Cl. CPC H01L 43/08; H01L 43/14; H01L 43/10; G01R 33/093; H01L 27/222; G11C 11/161; H01L 43/04

(57) ABSTRACT

A spin current magnetization rotational magnetoresistance effect element includes a magnetoresistance effect element including a first ferromagnetic metal layer in which a direction of magnetization is fixed, a second ferromagnetic metal layer configured for a direction of magnetization to be changed, and a nonmagnetic layer provided between the first ferromagnetic metal layer and the second ferromagnetic metal layer and a spin-orbit torque wiring extending in a first direction intersecting a lamination direction of the magnetoresistance effect element and joined to the second ferromagnetic metal layer. Furthermore, in the spin current magnetization rotational magnetoresistance effect element, the spin-orbit torque wiring containing a pure spin current generation part made of a material that generates a pure spin current and a low resistance part made of a material having electric resistance lower than electrical resistance of the pure spin current generation part.

### RELATED APPLICATIONS

This is a Continuation-in-Part of U.S. patent application Ser. No. 15/778,174, filed May 22, 2018, which is a National Stage Application of PCT/JP2016/084995, filed Nov. 25, 2016, which in turn claims priority to Japanese Patent Application No. 2015-232334, filed Nov. 27, 2015, Japanese Patent Application No. 2016-053072, filed Mar. 16, 2016, Japanese Patent Application No. 2016-056058, filed Mar. 18, 2016, Japanese Patent Application No. 2016-210531, filed Oct. 27, 2016, and Japanese Patent Application No. 2016-210533, filed Oct. 27, 2016, the content of which is incorporated herein by reference.

### TECHNICAL FIELD

The present invention relates to a spin current magnetization rotational magnetoresistance effect element and a method of manufacturing a spin current magnetization rotational magnetoresistance effect element.

### BACKGROUND ART

A giant magnetoresistance (GMR) element formed of a multilayer film including a ferromagnetic layer and a nonmagnetic layer and a tunnel magnetoresistance (TMR) element in which an insulating layer (a tunnel barrier layer, a barrier layer) is used for a nonmagnetic layer are known. Generally, although a TMR element has a higher element resistance as compared with a GMR element, a magnetoresistance (MR) ratio of TMR element is larger than an MR ratio of a GMR element. Therefore, attention is focused on the TMR element as an element for magnetic sensors, high frequency components, magnetic heads, and magnetic random access memories (MRAMs).

As a writing method of MRAMs, a method of performing writing (magnetization rotation) by utilizing a magnetic field generated by a current, and a method of performing writing (magnetization rotation) by utilizing a spin transfer torque (STT) generated by causing a current to flow in a laminating direction of a magnetoresistance element are known.

In the system using the magnetic field, since there is a limit to an amount of current flowing through a thin wiring, there is a problem in that writing becomes impossible when a size of an element becomes small.

In contrast, in the system using the spin transfer torque (STT), one ferromagnetic layer (fixed layer, reference layer) spin-polarizes a current, a spin of the current is transferred to magnetization of another ferromagnetic layer (free layer, recording layer), and thereby writing (magnetization rotation) is performed by the torque (STT) generated at that time. Therefore, there is an advantage in that, as a size of the element becomes smaller, a current required for writing can be smaller.

However, in the magnetoresistance effect element using the STT, it is necessary to cause an inversion current for causing magnetization rotation to flow in a lamination direction of the magnetoresistance effect element. The current flowing in the lamination direction adversely affects a life span of the magnetoresistance effect element.

Therefore, in recent years, it has been proposed that magnetization rotation utilizing spin-orbit interaction induced by a pure spin current can be used for applications (for example, Non Patent Literature 1).

The magnetoresistance effect element in which the spin-orbit interaction is performed induces a spin-orbit torque (SOT) by a pure spin current and the SOT causes magnetization rotation to occur. The pure spin current is generated when the same number of upward spin electrons and downward spin electrons flow in opposite directions to each other. Since a flow of electric charge as a whole is canceled out, an amount of current is zero even though the pure spin current flows.

The pure spin current flows in a direction perpendicular to a direction of current flow. Therefore, in the magnetoresistance effect element using the SOT, an inversion current for inducing magnetization rotation flows in a direction intersecting a lamination direction of the magnetoresistance effect element.

In other words, in the magnetoresistance effect element using an SOT, it is not necessary to flow a current in a lamination direction of the magnetoresistance effect element, and a prolonged life is expected.

### CITATION LIST

### Non Patent Literature

[Non Patent Literature 1]

I. M. Miron, K. Garello, G. Gaudin, P. -J. Zermatten, M. V. Costache, S. Auffret, S. Bandiera, B. Rodmacq, A. Schuhl, and P. Gambardella, Nature, 476, 189 (2011).

### SUMMARY OF INVENTION

### Technical Proble

Studies for magnetoresistance effect elements using a spin-orbit torque (SOT) have just begun. Thus, a clear configuration has not been determined, but a top pin structure in which a free layer is provided on a substrate side is widely used.

An SOT induced by a pure spin current is greatly affected by an interface of laminated layers. In order to obtain a large SOT, interfaces are required to be uniform. Generally, in a laminate, as a layer is closer to a substrate, influence of each layer laminated becomes smaller and homogeneous. Therefore, in order to efficiently supply a pure spin current to the free layer, a top pin structure is employed.

On the other hand, in a magnetoresistance effect element using STT, a bottom pin structure is also widely employed. This is because, since a fixed layer is on a substrate side, magnetization is stabilized and generation of noise is inhibited.

This bottom pin structure can also be applied, in principle, to the magnetoresistance effect element using the SOT. However, when the bottom pin structure is actually applied to the magnetoresistance effect element using the SOT, there is a problem in that a laminated interface is disturbed and a pure spin current is not efficiently supplied to the free layer. The present invention has been made in view of the above-described problems, and it is an object of the present disclosure is to provide a magnetoresistance effect element capable of efficiently utilizing an SOT induced by a pure spin current and a manufacturing method thereof.

### Solution to Problem

(1) A spin current magnetization rotational magnetoresistance effect element according to a first aspect includes a substrate, a magnetoresistance effect element provided on the substrate and including a first ferromagnetic metal layer in which a direction of magnetization is fixed, a nonmagnetic layer, a second ferromagnetic metal layer configured for a direction of magnetization to be changed, and a cap layer in an order from the substrate side, and a spin-orbit torque wiring extending in a first direction intersecting a lamination direction of the magnetoresistance effect element and joined to the cap layer, in which the cap layer includes one or more substances having high spin conductivity selected from the group consisting of Cu, Ag, Mg, Al, Si, Ge, and GaAs as a major component.

(2) In the spin current magnetization rotational magnetoresistance effect element according to the above aspect, a thickness of the cap layer may be equal to or less than a spin diffusion length of a substance constituting the major component of the cap layer.

(3) The spin current magnetization rotational magnetoresistance effect element according to a second aspect includes a magnetoresistance effect element including a first ferromagnetic metal layer in which a direction of magnetization is fixed, a nonmagnetic layer, a second ferromagnetic metal layer configured for a direction of magnetization to be changed, and a cap layer in an order, and a spin-orbit torque wiring extending in a first direction intersecting a lamination direction of the magnetoresistance effect element and joined to the cap layer, in which the cap layer has spin conductivity, and the magnetoresistance effect element further includes a diffusion prevention layer between the second ferromagnetic metal layer and the cap layer.

(4) In the spin current magnetization rotational magnetoresistance effect element according to the above aspect, the diffusion prevention layer may have at least one selected from a magnetic element and an element having an atomic number equal to or higher than that of yttrium.

(5) In the spin current magnetization rotational magnetoresistance effect element according to the above aspect, a thickness of the diffusion prevention layer may be equal to or less than four times an atomic radius of an atom constituting the diffusion prevention layer.

(6) In the spin current magnetization rotational magnetoresistance effect element according to the above aspect, the spin-orbit torque wiring may include a nonmagnetic metal having an atomic number of 39 or higher having a d electron or an f electron in an outermost shell.

(7) In the spin current magnetization rotational magnetoresistance effect element according to the above aspect, the spin-orbit torque wiring may be formed of a pure spin current generation part made of a material that generates a pure spin current, and a low resistance part made of a material having electric resistance lower than electrical resitance of the pure spin current generation part, and at least a part of the pure spin current generation part may be in contact with the cap layer.

(8) The spin current magnetization rotational magnetoresistance effect element according to a third aspect includes a magnetoresistance effect element including a first ferromagnetic metal layer in which a direction of magnetization is fixed, a second ferromagnetic metal layer configured for a direction of magnetization to be changed, and a nonmagnetic layer provided between the first ferromagnetic metal layer and the second ferromagnetic metal layer and a spin-orbit torque wiring extending in a first direction intersecting a lamination direction of the magnetoresistance effect element and joined to the second ferromagnetic metal layer, in which the spin-orbit torque wiring contains a pure spin current generation part made of a material that generates a pure spin current and a low resistance part made of a material having electric resistance lower than electrical resistance of the pure spin current generation part, at least a part of the pure spin current generation part is in contact with the second ferromagnetic metal layer, the pure spin current generation part is coated with the low resistance part, the low resistance part has a first convex shape portion projecting in a thickness direction of the low resistance part, and the first convex shape portion is provided on a position which is superimposed on at least the magnetoresistance effect element in a plan view from the lamination direction of the magnetoresistance effect element.

(9) In the spin current magnetization rotational magnetoresistance effect element according to the above aspect, the low resistance part has second convex shape portions projecting in the thickness direction of the low resistance part, and in a plan view from the lamination direction of the magnetoresistance effect element, each of the second convex shape portions is provided on both ends of the first convex shape portion in the first direction.

(10) In the spin current magnetization rotational magnetoresistance effect element according to the above aspect, the spin-orbit torque wiring includes a nonmagnetic metal having an atomic number of 39 or higher having a d electron or an f electron in an outermost shell.

(11) A magnetic memory according to a third aspect includes the spin current magnetization rotational magnetoresistance effect element described above.

(12) A method of manufacturing a spin current magnetization rotational magnetoresistance effect element including the steps of: forming a laminate in which a first ferromagnetic metal layer in which a direction of magnetization is fixed, a nonmagnetic layer, a second ferromagnetic metal layer configured for a direction of magnetization to be changed, a cap layer, and a process protection layer are laminated in an order on a substrate; processing the laminate into a predetermined shape to form a magnetoresistance effect element; and removing the process protection layer and forming a spin-orbit torque wiring on an exposed surface exposed after the removal.

### Advantageous Effects of Invention

According to the spin current magnetization rotational magnetoresistance effect element according to the above aspects, a spin-orbit torque (SOT) induced by a pure spin current can be efficiently utilized.

### BRIEF DESCRIPTION OF DRAWINGS

FIG. 1 is a perspective view schematically illustrating a spin current magnetization rotational magnetoresistance effect element according to a first embodiment.

FIG. 2 is a schematic view for describing a spin Hall effect.

FIG. 3 is a schematic view for describing one embodiment of a spin-orbit torque wiring, in which (a) is a cross-sectional view and (b) is a plan view.

FIG. 4 is a schematic view for describing another embodiment of the spin-orbit torque wiring, in which (a) is a cross-sectional view and (b) is a plan view.

FIG. 5 is a schematic view for describing another embodiment of the spin-orbit torque wiring, in which (a) is a cross-sectional view and (b) is a plan view.

FIG. 6 is a schematic view for describing another embodiment of the spin-orbit torque wiring, in which (a) is a cross-sectional view and (b) is a plan view.

FIG. 7 is a perspective view schematically illustrating a spin current magnetization rotational magnetoresistance effect element according to a second embodiment.

FIG. 8 is a view illustrating a manufacturing method of a spin current magnetization rotational magnetoresistance effect element according to the present embodiment.

FIG. 9 is a schematic cross-sectional view of the spin current magnetization rotational magnetoresistance effect element according to the present embodiment taken along an xz plane.

FIG. 10 is a schematic cross-sectional view of another example of the spin current magnetization rotational magnetoresistance effect element according to the present embodiment taken along the xz plane.

FIG. 11 is a perspective view schematically illustrating the spin current magnetization rotational magnetoresistance effect element according to the present embodiment including a power supply.

FIG. 12 is a schematic view for describing another embodiment of the spin-orbit torque wiring, in which (a) is a cross-sectional view and (b) is a plan view.

FIG. 13 is a schematic view for describing another embodiment of the spin-orbit torque wiring, in which (a) is a cross-sectional view and (b) is a plan view.

### DESCRIPTION OF EMBODIMENTS

Hereinafter, the present embodiment will be described in detail with reference to the drawings as appropriate. In the drawings used in the following description, there are cases in which characteristic portions are appropriately enlarged for convenience of illustration so that characteristics of the present disclosure can be easily understood, and dimensional ratios of respective constituent elements may be different from actual ones. Materials, dimensions, and the like illustrated in the following description are merely examples, and the present disclosure is not limited thereto but can be implemented with appropriate modifications within the range in which the effect of the present disclosure is achieved.

(Spin Current Magnetization Rotational Magnetoresistance Effect Element)

### First Embodiment

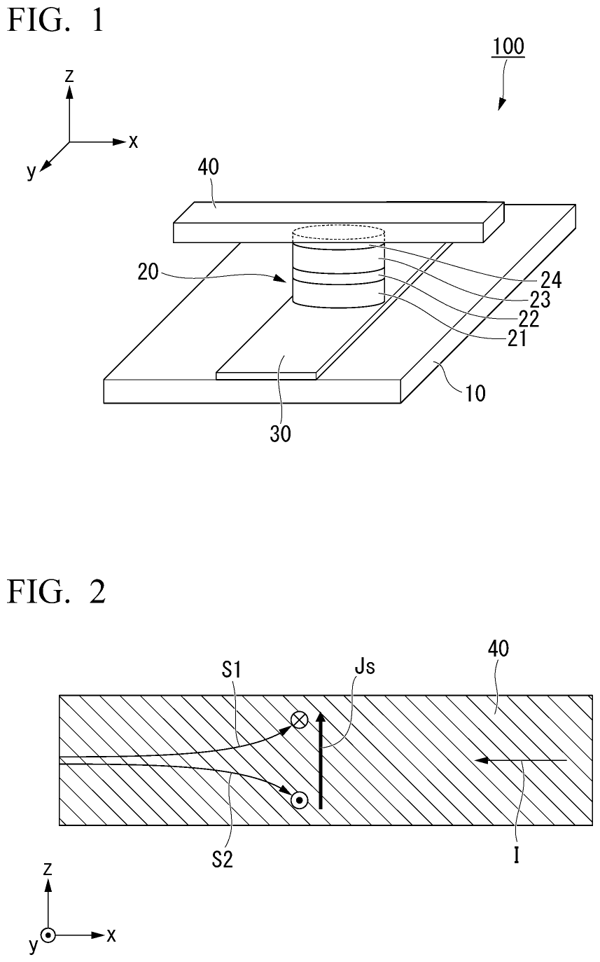

FIG. 1 is a perspective view schematically illustrating a spin current magnetization rotational magnetoresistance effect element according to a first embodiment.

As illustrated in FIG. 1, the spin current magnetization rotational magnetoresistance effect element 100 includes a substrate 10, a magnetoresistance effect element 20, and a spin-orbit torque wiring 40. In FIG. 1, a wiring 30 for causing a current to flow in a lamination direction of the magnetoresistance effect element 20 is also illustrated. The spin-orbit torque wiring 40 is joined to the magnetoresistance effect element 20 and extends in a direction intersecting the lamination direction of the magnetoresistance effect element 20.

Hereinafter, as an example of a configuration in which the spin-orbit torque wiring extends in a direction intersecting the lamination direction of the magnetoresistance effect element, a case of a configuration in which the spin-orbit torque wiring extends in a direction perpendicular to the lamination direction of the magnetoresistance effect element will be described.

Hereinafter, the lamination direction of the magnetoresistance effect element 20 is a z direction, a direction thereof perpendicular to the z direction and parallel to the spin-orbit torque wiring 40 is an x direction, and a direction thereof perpendicular to the x direction and z direction is a y direction.

<Substrate>

The substrate 10 is preferably excellent in flatness. In order to obtain a surface excellent in flatness, for example, a semiconductor such as Si, Ge, GaAs, or InGaAs, or AlTiC or the like can be used as a material. Further, the substrate 10 may have a circuit on a material such as a semiconductor such as Si, Ge, GaAs, or InGaAs, or AlTiC or the like.

<Magnetoresistance Effect Element>

The magnetoresistance effect element 20 includes a first ferromagnetic metal layer 21, a nonmagnetic layer 22, a second ferromagnetic metal layer 23, and a cap layer 24 in that order from the substrate 10 side.

The magnetoresistance effect element 20 may include a first ferromagnetic metal layer 21, a nonmagnetic layer 22, and a second ferromagnetic metal layer 23 in that order from the substrate 10 side.

Magnetization of the first ferromagnetic metal layer 21 is fixed in one direction and a direction of magnetization of the second ferromagnetic metal layer 23 changes relative to the magnetization of the first ferromagnetic metal layer 21 to function as the magnetoresistance effect element 20. When it is applied to a coercivity-differed type (pseudo spin valve type) magnetic random access memory (MRAM), coercivity of the first ferromagnetic metal layer 21 is larger than coercivity of the second ferromagnetic metal layer 23. In addition, when it is applied to an exchange bias type (spin valve type) MRAM, a direction of magnetization of the first ferromagnetic metal layer 21 is fixed by exchange coupling with an antiferromagnetic layer.

When the nonmagnetic layer 22 is formed of an insulator, the magnetoresistance effect element 20 is a tunneling magnetoresistance (TMR) element, and when the nonmagnetic layer 22 is formed of a metal, the magnetoresistance effect element 20 is a giant magnetoresistance (GMR) element.

For the magnetoresistance effect element according to the embodiment, a configuration of a known magnetoresistance effect element can be employed. For example, each layer may be formed of a plurality of layers, or another layer such as an antiferromagnetic layer for fixing a direction of magnetization of the first ferromagnetic metal layer may be provided. The first ferromagnetic metal layer 21 is called a fixed layer, a reference layer, or the like, and the second ferromagnetic metal layer 23 is called a free layer, a storage layer, or the like.

The first ferromagnetic metal layer 21 is disposed on the substrate 10 side with respect to the second ferromagnetic metal layer 23. When the first ferromagnetic metal layer 21 serving as a fixed layer is disposed on the substrate 10 side, magnetization of the first ferromagnetic metal layer 21 is stabilized. When the magnetization of the first ferromagnetic metal layer 21 is stabilized, fluctuation of background of a magnetoresistance (MR) ratio is inhibited, and noise of the magnetoresistance effect element 20 is reduced.

The first ferromagnetic metal layer 21 and the second ferromagnetic metal layer 23 may be either an in-plane magnetization film of which a magnetization direction is an in-plane direction parallel to the layer or a perpendicular magnetization film of which a magnetization direction is a direction perpendicular to the layer.

As a material of the first ferromagnetic metal layer 21, a known material can be used. For example, a metal selected from the group consisting of Cr, Mn, Co, Fe and Ni, and an alloy containing one or more of these metals and exhibiting ferromagnetism can be used. It is also possible to use an alloy containing these metals and at least one of the elements B, C, and N. Specifically, Co—Fe or Co—Fe—B can be exemplified.

In order to obtain a higher output, it is preferable to use a Heusler alloy such as Co₂FeSi as a material of the first ferromagnetic metal layer 21. A Heusler alloy contains an intermetallic compound having a chemical composition of X₂YZ, and X indicates a transition metal element of Co, Fe, Ni, or Cu group, or a noble metal element in the periodic table. Y indicates a transition metal of Mn, V, Cr, or Ti group, and can also be elemental species of X. Z indicates a typical element from Group III to Group V. Co₂FeSi, Co₂MnSi, Co₂Mn₁₋ₐFeₐAl_{b}Si_{1-b}, and the like can be exemplified as a Heusler alloy.

An antiferromagnetic material such as IrMn, PtMn or the like may be brought into contact with a surface of the first ferromagnetic metal layer 21 opposite to the second ferromagnetic metal layer 23. Coercivity of the first ferromagnetic metal layer 21 with respect to the second ferromagnetic metal layer 23 can be further increased. Further, the magnetoresistance effect element 20 may have a synthetic ferromagnetic coupling structure to prevent a leakage magnetic field of the first ferromagnetic metal layer 21 from affecting the second ferromagnetic metal layer 23.

When a direction of magnetization of the first ferromagnetic metal layer 21 is made perpendicular to a lamination surface, it is preferable to use a film in which Co and Pt are laminated. Specifically, the first ferromagnetic metal layer 21 is formed of [Co (0.24 nm)/Pt (0.16 nm)]₆/Ru (0.9 nm)/[Pt (0.16 nm)/Co (0.16 nm)]₄/T (0.2 nm)/FeB (1.0 nm).

As the second ferromagnetic metal layer 23, a ferromagnetic material, particularly a soft magnetic material, can be applied. For example, a metal selected from the group consisting of Cr, Mn, Co, Fe and Ni, an alloy containing one or more of these metals, and an alloy containing these metals and at least one of the elements B, C, and N, or the like can be used. Specifically, Co—Fe, Co—Fe—B, Ni—Fe can be exemplified.

When a direction of magnetization of the second ferromagnetic metal layer 23 is made perpendicular to the lamination surface, a thickness of the second ferromagnetic metal layer is preferably 2.5 nm or less. Perpendicular magnetic anisotropy can be added to the second ferromagnetic metal layer 23 at an interface between the second ferromagnetic metal layer 23 and the nonmagnetic layer 22. A film thickness of the second ferromagnetic metal layer 23 is preferably small. An effect of the perpendicular magnetic anisotropy is attenuated when the film thicknesses of the second ferromagnetic metal layer 23 increases.

For the nonmagnetic layer 22, a known material can be used.

For example, when the nonmagnetic layer 22 is formed of an insulator (in the case of a tunnel barrier layer), Al₂O₃, SiO₂, Mg, MgAl₂O₄O, or the like can be used as the material. In addition to these materials, a material in which a part of Al, Si, and Mg is substituted with Zn, Be or the like can also be used as the tunnel barrier layer. Of these, MgO and MgAl₂O₄ are materials that can realize coherent tunneling, and spin can be efficiently injected into the second ferromagnetic metal layer 23.

When the nonmagnetic layer 22 is formed of a metal, Cu, Au, Ag, or the like can be used as the material.

The cap layer 24 is a layer connecting the second ferromagnetic metal layer 23 to the spin-orbit torque wiring 40. Although details will be described in a manufacturing method to be described below, the cap layer 24 is a layer that can be polished during a manufacturing process. Therefore, when the cap layer 24 is provided on the second ferromagnetic metal layer 23, a surface on which the spin-orbit torque wiring 40 is laminated can be planarized.

A spin-orbit torque (SOT) accompanying a pure spin current is greatly affected by an interface of the lamination surface. When the interface between the cap layer 24 and the spin-orbit torque wiring 40 is planarized, a pure spin current can be efficiently supplied to the second ferromagnetic metal layer 23, and a large SOT can be obtained.

On the other hand, the pure spin current generated in the spin-orbit torque wiring 40 passes through the cap layer 24 before reaching the second ferromagnetic metal layer 23. Although the cap layer 24 is a layer needed for planarizing the interface, when the spin passing through the cap layer 24 is diffused, a sufficient pure spin current cannot be supplied to the second ferromagnetic metal layer 23.

Therefore, the cap layer 24 preferably does not easily dissipate the spin transferred from the spin-orbit torque wiring 40. That is, the cap layer 24 is required to have spin conductivity, and it is preferable to mainly have a substance having high spin conductivity.

Copper, silver, magnesium, aluminum, silicon, germanium, gallium arsenide, and the like have long spin diffusion lengths of 100 nm or more even at room temperature, and do not easily dissipate spin. Therefore, it is preferable that the cap layer 24 mainly has one or more elements selected from the group consisting of these materials.

A thickness of the cap layer 24 is preferably equal to or less than the spin diffusion length of the substance forming the cap layer 24. When the thickness of the cap layer 24 is equal to or less than the spin diffusion length, the spin transferred from the spin-orbit torque wiring 40 can be sufficiently transferred to the magnetoresistance effect element 20.

Further, the cap layer 24 also contributes to a crystal orientation of each layer of the magnetoresistance effect element 20. The cap layer 24 stabilizes magnetism of the first ferromagnetic metal layer 21 and the second ferromagnetic metal layer 23 of the magnetoresistance effect element 20, and contributes to low resistance of the magnetoresistance effect element 20.

<Spin-Orbit Torque Wiring>

The spin-orbit torque wiring 40 extends in a first direction intersecting the lamination direction of the magnetoresistance effect element 20. A power supply for causing a current to flow along the spin-orbit torque wiring 40 is electrically connected to the spin-orbit torque wiring 40. The spin-orbit torque wiring 40 and the power supply function as spin injection means for injecting a pure spin current into the magnetoresistance effect element.

The spin-orbit torque wiring 40 is made of a material in which a pure spin current is generated by a spin Hall effect when a current flows. As such a material, any material may be sufficient as long as it has a configuration in which a pure spin current is generated in the spin-orbit torque wiring 40. Therefore, it is not limited to a material formed of a single element, but a material formed of a part configured with a material from which a pure spin current is generated and a part configured with a material from which no pure spin current is generated, or the like may be used.

The spin Hall effect is a phenomenon in which a pure spin current is induced in a direction perpendicular to a current direction on the basis of spin-orbit interaction when a current flows in a material.

FIG. 2 is a schematic view for describing a spin Hall effect. A mechanism in which a pure spin current is generated by the spin Hall effect will be described with reference to FIG. 2.

As illustrated in FIG. 2, when a current I flows in an extending direction of the spin-orbit torque wiring 40, a first spin S1 and a second spin S2 are respectively bent in a direction perpendicular to the current. A normal Hall effect and a spin Hall effect are common in that motion (movement) of electric charges (electrons) is bent in a motion (movement) direction. On the other hand, while charged particles moving in a magnetic field are subjected to a Lorentz force and a direction of the motion is bent in the normal Hall effect, the spin Hall effect is greatly different in that, even though there is no magnetic field, when electrons merely move (when a current merely flows), a moving direction thereof is bent.

Since the number of electrons of the first spin 51 is equal to the number of electrons of the second spin S2 in a nonmagnetic material (a material which is not a ferromagnetic material), the number of electrons of the first spin 51 directed upward and the number of electrons of the second spin S2 directed downward in the drawing are the same. Therefore, the current as a net flow of electric charges is zero. This spin current that does not accompany a current is particularly called a pure spin current.

On the other hand, also when a current flows through a ferromagnetic material, it is the same point in that first spin electrons and second spin electrons are bent in opposite directions from each other. However, since a ferromagnetic material is in a state in which either the first spin electrons or the second spin electrons are more than the other, as a result, a net flow of electric charges occurs (a voltage is generated). Therefore, as a material of the spin-orbit torque wiring, a material formed of only a ferromagnetic material is not included.

Here, when a flow of electrons in the first spin 51 is expressed as J_{↑}, a flow of electrons in the second spin S2 is expressed as J_{θ}, and a spin current is expressed as Jₛ, it is defined by Jₛ=J_{↑}−J_{↓}. In FIG. 2, the pure spin current Jₛ flows upward in the drawing. Here, Jₛ is a flow of electrons with a polarizability of 100%.

In FIG. 2, when a ferromagnetic material is brought into contact with an upper surface of the spin-orbit torque wiring 40, the pure spin current diffuses and flows into the ferromagnetic material. In the present embodiment, the pure spin current generated by causing a current to flow through the spin-orbit torque wiring 40 diffuses into the second ferromagnetic metal layer 23 via the cap layer 24. The magnetization of the second ferromagnetic metal layer 23 serving as a free layer is rotated in magnetization due to the spin-orbit torque (SOT) effect by the pure spin current.

Magnetization rotation is not necessarily performed using only the SOT effect. For example, magnetization rotation may be performed using a spin transfer torque (STT) effect together with the SOT. In addition, an external magnetic field, heat, a voltage, lattice distortion, or the like may be used together with the SOT.

The spin-orbit torque wiring 40 may include a nonmagnetic heavy metal. Here, “heavy metal” is used to mean a metal having a specific gravity equal to or higher than that of yttrium. The spin-orbit torque wiring 40 may be formed of only a nonmagnetic heavy metal.

In this case, the nonmagnetic heavy metal is preferably a nonmagnetic metal having a high atomic number such as the atomic number of 39 or higher having a d electron or an f electron in an outermost shell. Nonmagnetic metals have a large spin-orbit interaction which causes a spin Hall effect. The spin-orbit torque wiring 40 may be formed of only a nonmagnetic metal having a high atomic number such as the atomic number of 39 or higher having a d electron or an f electron in an outermost shell.

Normally, when a current flows in a metal, all of the electrons move in a direction opposite to the current regardless of a direction of their spin. In contrast, since the nonmagnetic metal with a high electron number having d electrons and f electrons in an outermost shell has a large spin-orbit interaction, a movement direction of electrons depends on a spin direction of electrons due to the spin Hall effect and the pure spin current Jₛ is easily generated.

The spin-orbit torque wiring 40 may include a magnetic metal. The magnetic metal indicates a ferromagnetic metal or an antiferromagnetic metal. When a very small amount of magnetic metal is contained in a nonmagnetic metal, the spin-orbit interaction is enhanced and spin current generation efficiency with respect to a current flowing through the spin-orbit torque wiring 40 increases. The spin-orbit torque wiring 40 may be formed of only an antiferromagnetic metal.

Since spin-orbit interaction is caused by an inherent inner space of a substance of the spin-orbit torque wiring material, a pure spin current is generated even in a nonmagnetic material. When a very small amount of a magnetic metal is added to the spin-orbit torque wiring material, the magnetic metal itself scatters electron spins flowing therethrough and the spin current generation efficiency increases.

However, when an additive amount of the magnetic metal is excessively increased, the generated pure spin current is scattered by the added magnetic metal, and as a result, an effect of decreasing the spin current increases. Therefore, a molar ratio of the added magnetic metal is preferably sufficiently smaller than a molar ratio of a major component of a pure spin generation part in the spin-orbit torque wiring. As a reference, the molar ratio of the added magnetic metal is preferably 3% or less.

The spin-orbit torque wiring 40 may include a topological insulator. The spin-orbit torque wiring 40 may be formed of only the topological insulator. The topological insulator is a material in which the interior of the substance is an insulator or a highly resistive material while a spin-polarized metallic state is generated on a surface thereof.

In a substance, there is something like an internal magnetic field called spin-orbit interaction. Due to an effect of this spin-orbit interaction, a new topological phase is exhibited even without an external magnetic field. This is the topological insulator and it can generate the pure spin current with high efficiency by strong spin-orbit interaction and breaking of rotation symmetry at an edge.

As the topological insulator, for example, SnTe, Bi_{1.5}Sb_{0.5}Te_{1.7}Se_{1.3}, TlBiSe₂, Bi₂Te₃, (Bi₁₋ₓSbₓ)₂Te₃, and the like are preferable. These topological insulators can generate the spin current with high efficiency.

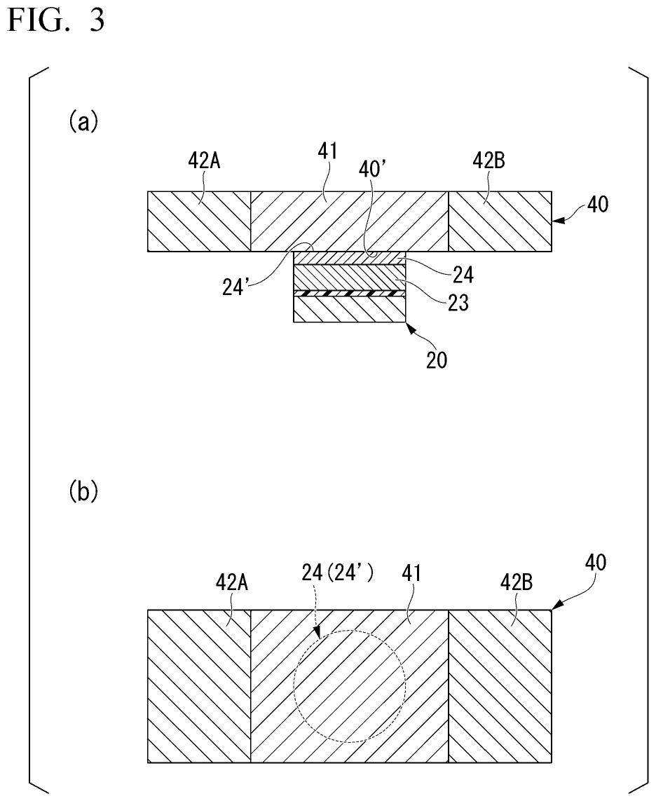

FIGS. 3 to 6, 12 and 13 are schematic views for describing embodiments of the spin-orbit torque wiring, in which (a) is a cross-sectional view and (b) is a plan view.

A heavy metal, which is a material capable of generating a pure spin current, has higher electric resistance as compared with a metal used for an ordinary wiring. Therefore, in view of reducing Joule heat, it is preferable that the spin-orbit torque wiring 40 include a part with low electric resistance, rather than the entire spin-orbit torque wiring 40 being made of a material capable of generating the pure spin current. That is, it is preferable that the spin-orbit torque wiring 40 be formed of a part (pure spin current generation part) made of a material that generates a pure spin current and a part (low resistance part) made of a material having a lower electric resistance than the pure spin current generation part.

The pure spin current generation part may be made of a material capable of generating a pure spin current, and may have, for example, a configuration constituted by a plurality of types of material parts, or the like.

For the low resistance part, a material used for a normal wiring can be used. For example, aluminum, silver, copper, gold, or the like can be used. The low resistance part may be made of a material having lower electric resistance than the pure spin current generation part, and may have, for example, a configuration constituted by a plurality of types of material parts, or the like.

Further, the low resistance part is not limited to one that does not generate a pure spin current, and one generating a pure spin current may also be used. In this case, in regard to distinction between the pure spin current generation part and the low resistance part, the parts formed of the materials described as the materials of the pure spin current generation part and the low resistance part in this specification can be distinguished as being the pure spin current generation part or the low resistance part. In addition, a part other than a main part generating the pure spin current and having a lower electric resistance than the main part is the low resistance part and can be distinguished from the pure spin current generation part.

The pure spin current generation part may include a nonmagnetic heavy metal. A heavy metal capable of producing a pure spin current may be included in a finite amount. A material composition of the pure spin current generation part is preferably one of the following two. One is a case in which a major component of the pure spin current generation part is occupied by a heavy metal capable of generating a pure spin current, and another is a case in which a heavy metal capable of generating a pure spin current occupies a sufficiently smaller concentration region than that of a major component of the pure spin current generation part.

When the major component of the pure spin current generation part is occupied by the heavy metal capable of generating a pure spin current, a ratio thereof is preferably 90% or more, or is preferably 100%. The heavy metal in this case is a nonmagnetic metal having an atomic number of 39 or higher having a d electron or an f electron in an outermost shell.

On the other hand, as an example of a case in which a concentration occupied by the heavy metal capable of generating a pure spin current is much smaller than that of the major component of the pure spin current generation part, a case in which the major component of the pure spin current generation part is copper and the heavy metal is contained at a concentration of 10% or less in terms of molar ratio can be exemplified.

As described above, when the heavy metal capable of generating a pure spin current occupies a sufficiently smaller concentration region than that of the major component of the pure spin current generation part, a concentration of the heavy metal contained in the pure spin current generation part is preferably 50% or less, more preferably 10% or less, in terms of molar ratio. When a concentration range of the heavy metal is within the above range, a spin scattering effect by electrons can be effectively obtained.

Here, when the heavy metal capable of a generating pure spin current occupies a sufficiently smaller concentration region than that of the major component of the pure spin current generation part, the major component constituting the pure spin current generation part is formed of one other than the above-described heavy metals. In other words, a main part constituting the pure spin current generation part is a light metal having an atomic number smaller than that of the heavy metal, and the other part is the heavy metal.

An assumption here is that the heavy metal and the light metal do not form an alloy, but atoms of the heavy metal are randomly dispersed in the light metal. Spin-orbit interaction is weak in a light metal and a pure spin current due to the spin Hall effect cannot easily be generated in the light metal which is the major component. However, when a heavy metal is contained in the light metal, spins are scattered at an interface between the light metal and the heavy metal when electrons pass through the heavy metal in the light metal. As a result, it is possible to efficiently generate the pure spin current even when a concentration of the heavy metal is low.

On the other hand, when a concentration of the heavy metal exceeds 50%, although a ratio of the spin Hall effect in the heavy metal increases, the effect at the interface between the light metal and the heavy metal decreases, and thus the effect decreases as a whole. Therefore, a concentration of the heavy metal to such an extent that a sufficient interface effect can be expected is preferable.

In addition, the pure spin current generation part can be formed of an antiferromagnetic metal. This is an example of a case in which the spin-orbit torque wiring 40 described above includes a magnetic metal. When the pure spin current generation part is formed of an antiferromagnetic metal, it is possible to obtain the same effect as in a case in which the nonmagnetic heavy metal with an atomic number 39 or more having a d electron or an f electron in an outermost shell is 100%. The antiferromagnetic metal is, for example, preferably IrMn or PtMn, and IrMn that is stable to heat is more preferable.

In addition, the pure spin current generation part can be formed of a topological insulator. This is an example of a case in which the spin-orbit torque wiring described above includes a topological insulator. As the topological insulator, for example, SnTe, Bi_{1.5}Sb_{0.5}Te_{1.7}Se_{1.3}, TlBiSe₂, Bi₂Te₃, (Bi₁₋ₓSbₓ)₂Te₃ and the like are preferable. These topological insulators can generate a spin current with high efficiency.

In order for the pure spin current generated in the spin-orbit torque wiring to effectively diffuse into the magnetoresistance effect element, at least a part of the pure spin current generation part needs to be in contact with the magnetoresistance effect element 20. All of the embodiments of the spin-orbit torque wiring illustrated in FIGS. 3 to 6 have a configuration in which the pure spin current generation part is in contact with the cap layer 24 at least in part.

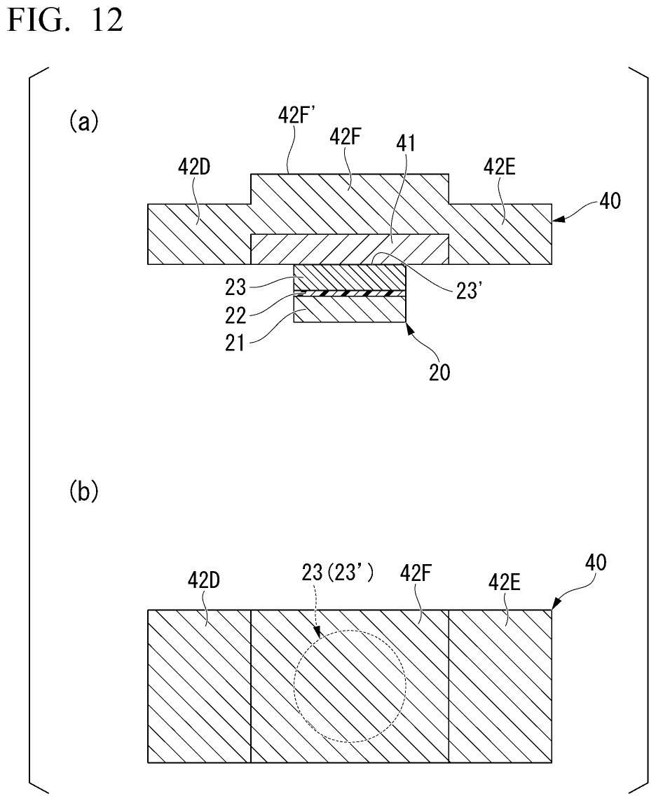

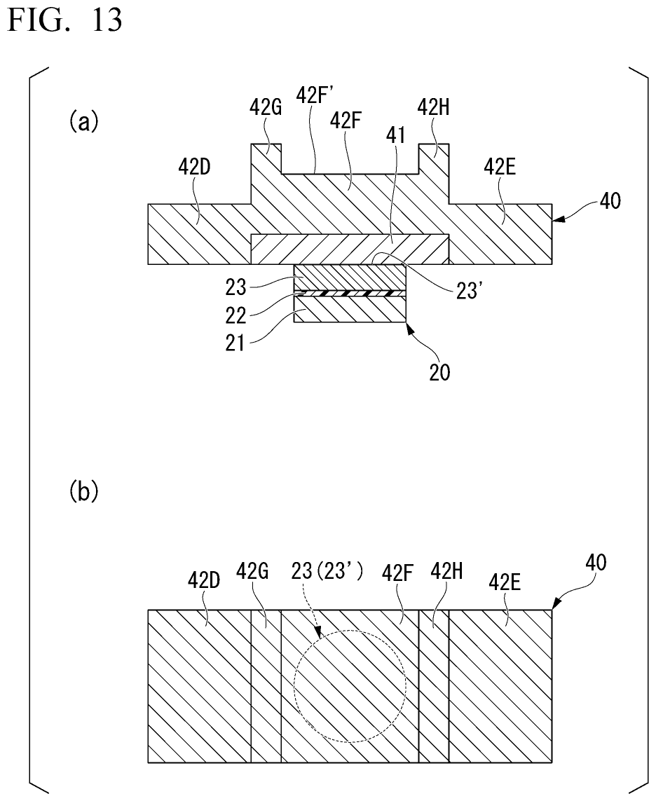

All of the embodiments of the spin-orbit torque wiring illustrated in FIGS. 12 and 13 have a configuration in which the pure spin current generation part is in contact with the second ferromagnetic metal layer 23 at least in part. In FIGS. 12 and 13, the cap layer may be provided between the second ferromagnetic metal layer 23 and the spin-orbit torque wiring 40. When the cap layer is provided between the second ferromagnetic metal layer 23 and the spin-orbit torque wiring 40, the embodiments of the spin-orbit torque wiring illustrated in FIGS. 12 and 13 have a configuration in which the pure spin current generation part is in contact with the cap layer 24 at least in part.

In the spin-orbit torque wiring 40 illustrated in FIG. 3, an entire junction 40′ with the cap layer 24 is formed of the spin current generation part 41, and the spin current generation part 41 is sandwiched between low resistance parts 42A and 42B.

Here, when the spin current generation part and the low resistance part are disposed electrically in parallel, a current flowing through the spin-orbit torque wiring is divided into proportions of an inverse ratio of magnitudes of resistances of the spin current generation part and the low resistance part, and thereby flows through respective parts.

In view of pure spin current generation efficiency, it is preferable that all the current flowing through the spin-orbit torque wiring flow through the spin current generation part. In other words, it is preferable that there be no part in which the spin current generation part and the low resistance part are electrically disposed in parallel, and that all be electrically disposed in series.

The spin-orbit torque wirings illustrated in FIGS. 3 to 6, 12 and 13 have configurations in which there is no part of the spin current generation part and the low resistance part that is electrically disposed in parallel in a plan view from the lamination direction of the magnetoresistance effect element. These configurations can increase the pure spin current generation efficiency.

In the spin-orbit torque wiring 40 illustrated in FIG. 3, the spin current generation part 41 is superimposed on a junction 24′ with the cap layer 24 to include the junction 24′ in a plan view from the lamination direction of the magnetoresistance effect element 20. A thickness direction of the spin-orbit torque wiring 40 is formed of only the spin current generation part 41, and the low resistance parts 42A and 42B sandwich the spin current generation part 41 in a direction of current flow. As a modified example of the spin-orbit torque wiring illustrated in FIG. 3, there are cases in which the spin current generation part 41 is superimposed on the junction 24′ of the cap layer 24 so that the junction 24′ is overlaid with the spin current generation part 41 in a plan view from the lamination direction of the magnetoresistance effect element 20. In this modified example, configurations other than this part are the same as the spin-orbit torque wiring illustrated in FIG. 3.

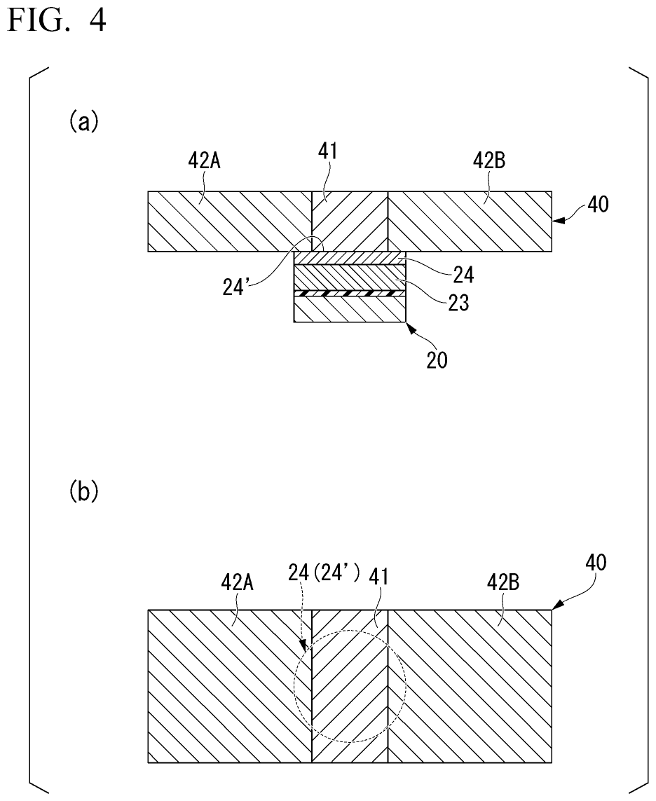

In the spin-orbit torque wiring 40 illustrated in FIG. 4, the spin current generation part 41 is superimposed on a part of the junction 24′ of the cap layer 24 in a plan view from the lamination direction of the magnetoresistance effect element 20. The thickness direction of the spin-orbit torque wiring 40 is formed of only the spin current generation part 41, and the low resistance parts 42A and 42B sandwich the spin current generation part 41 in a direction of current flow.

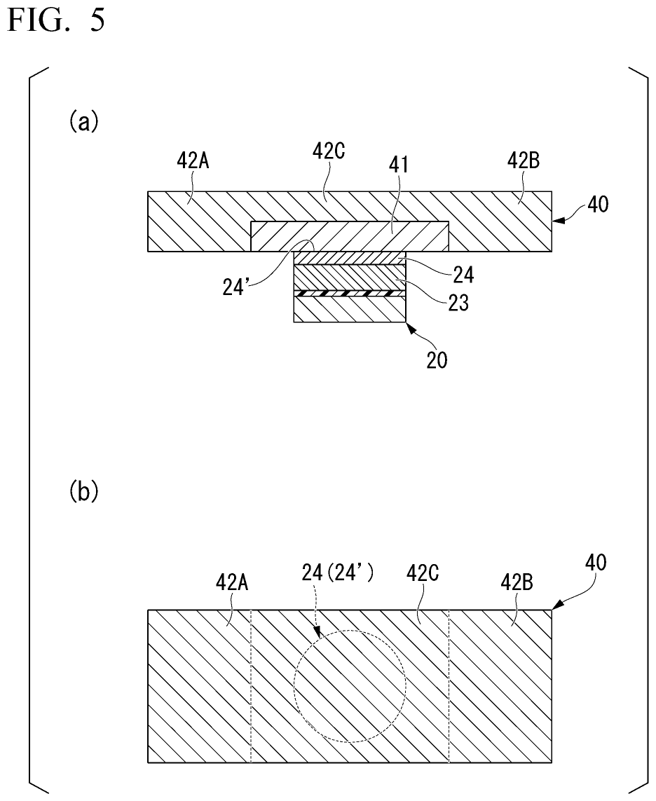

In the spin-orbit torque wiring 40 illustrated in FIG. 5, the spin current generation part 41 is superimposed on the junction 24′ of the cap layer 24 to include the junction 24′ in a plan view from the lamination direction of the magnetoresistance effect element 20. In the thickness direction of the spin-orbit torque wiring 40, the spin current generation part 41 and a low resistance part 42C are laminated in order from the magnetoresistance effect element 20 side. A part in which the spin current generation part 41 and the low resistance part 42C are laminated is sandwiched between the low resistance parts 42A and 42B in a direction of current flow. As a modified example of the spin-orbit torque wiring illustrated in FIG. 5, there are cases in which the spin current generation part 41 is superimposed on the junction 24′ of the cap layer 24 so that the junction 24′ is overlaid with the spin current generation part 41 in a plan view from the lamination direction of the magnetoresistance effect element 20. In this modified example, configurations other than this part are the same as the spin-orbit torque wiring illustrated in FIG. 5.

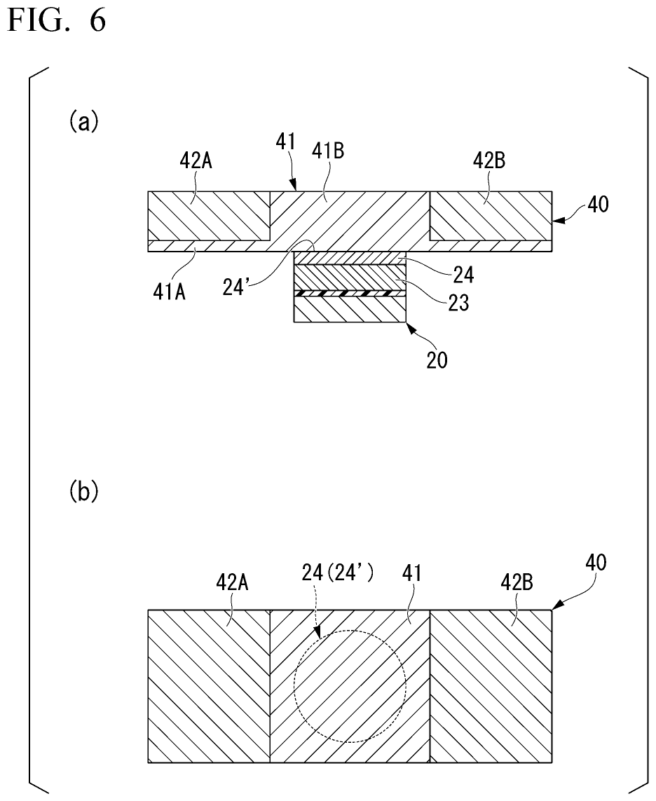

In the spin-orbit torque wiring 40 illustrated in FIG. 6, the spin current generation part 41 includes a first spin current generation part 41A and a second spin current generation part 41B. The first spin current generation part 41A is a part formed on an entire surface of the spin current generation part 41 on the magnetoresistance effect element 20 side. The second spin current generation part 41B is a part laminated on the first spin current generation part 41A and is a part superimposed on the junction 24′ of the cap layer 24 to include the junction 24′ in a plan view from the lamination direction of the magnetoresistance effect element 20. The second spin current generation part 41B is sandwiched between the low resistance parts 42A and 42B in a direction of current flow.

As a modified example of the spin-orbit torque wiring illustrated in FIG. 6, there are cases in which the second spin current generation part 41B is superimposed on the junction 24′ of the cap layer 24 so that the junction 24′ is overlaid with the second spin current generation part 41B in a plan view from the lamination direction of the magnetoresistance effect element 20. In this modified example, configurations other than this part are the same as the spin-orbit torque wiring illustrated in FIG. 6. In the configuration illustrated in FIG. 6, since an area of contact between the spin current generation part 41 and the low resistance part 42 is wide, the adhesion between the spin current generation part 41 and the low resistance part 42 is high.

In the spin-orbit torque wiring 40 illustrated in FIG. 12, the spin current generation part 41 is superimposed on the junction 23′ of the second ferromagnetic metal layer 23 to include the junction 23′ in a plan view from the lamination direction of the magnetoresistance effect element 20. In the thickness direction of the spin-orbit torque wiring 40, the spin current generation part 41 and a low resistance part 42F are laminated in order from the magnetoresistance effect element 20 side. A part in which the spin current generation part 41 and the low resistance part 42F are laminated is sandwiched between the low resistance parts 42D and 42E in a direction of current flow. The low resistance part 42F has a first surface which is in contact with the spin current generation part 41 and a second surface opposed to the first surface. The low resistance part 42F has a first convex shape portion 42F′ projecting in a thickness direction of the low resistance part 42F, and the first convex shape portion 42F′ is provided on a position which is superimposed on at least the magnetoresistance effect element 20 in a plan view from the lamination direction of the magnetoresistance effect element 20. That is, the first convex shape portion 42F′ is provided on the second surface of the low resistance part 42F and provided on the position which is superimposed on at least the magnetoresistance effect element 20 in a plan view from the lamination direction of the magnetoresistance effect element 20. The thickness of the first convex shape portion 42F′ is thicker than at least the thickness of the low resistance parts 42D and 42E.

By the above structure, in a plan view from the lamination direction of the magnetoresistance effect element 20, in the position which is superimposed on at least the magnetoresistance effect element 20, the thickness of the spin-orbit torque wiring 40 increases, thereby the thermal dissipation of the spin-orbit torque wiring 40 can be improved.

As a modified example of the spin-orbit torque wiring illustrated in FIG. 12, there are cases in which the spin current generation part 41 is superimposed on the junction 23′ of the second ferromagnetic metal layer 23 so that the junction 23′ is overlaid with the spin current generation part 41 in a plan view from the lamination direction of the magnetoresistance effect element 20. In this modified example, configurations other than this part are the same as the spin-orbit torque wiring illustrated in FIG. 12.

In the spin-orbit torque wiring 40 illustrated in FIG. 13, the spin current generation part 41 is superimposed on the junction 23′ of the second ferromagnetic metal layer 23 to include the junction 23′ in a plan view from the lamination direction of the magnetoresistance effect element 20. In the thickness direction of the spin-orbit torque wiring 40, the spin current generation part 41 and a low resistance part 42F are laminated in order from the magnetoresistance effect element 20 side. A part in which the spin current generation part 41 and the low resistance part 42F are laminated is sandwiched between the low resistance parts 42D and 42E in a direction of current flow.

The low resistance part 42F has a first surface which is in contact with the spin current generation part 41 and a second surface opposed to the first surface. The low resistance part 42F has a first convex shape portion 42F′ projecting in a thickness direction of the low resistance part 42F, and the first convex shape portion 42F′ is provided on a position which is superimposed on at least the magnetoresistance effect element 20 in a plan view from the lamination direction of the magnetoresistance effect element 20. That is, the first convex shape portion 42F′ is provided on the second surface of the low resistance part 42F and provided on the position which is superimposed on at least the magnetoresistance effect element 20 in a plan view from the lamination direction of the magnetoresistance effect element 20. The thickness of the first convex shape portion 42F′ is thicker than at least the thickness of the low resistance parts 42D and 42E.

Furthermore, in FIG. 13, in a plan view from the lamination direction of the magnetoresistance effect element 20, the low resistance part 42F has second convex shape portions 42G and 42H projecting in the thickness direction of the low resistance part 42F, and each of the second convex shape portions 42G and 42H is provided on both ends of the first convex shape portion 42F′. The both ends of the first convex shape portion 42F means that both ends of the first convex shape portion 42F in the first direction extending the spin-orbit torque wiring 40. The thickness of the second convex shape portions 42G and 42H is thicker than the thickness of the first convex shape portion 42F′.

By the above structure, the thermal dissipation of the spin-orbit torque wiring 40 can be more improved.

As a modified example of the spin-orbit torque wiring illustrated in FIG. 13, there are cases in which the spin current generation part 41 is superimposed on the junction 23′ of the second ferromagnetic metal layer 23 so that the junction 23′ is overlaid with the spin current generation part 41 in a plan view from the lamination direction of the magnetoresistance effect element 20. In this modified example, configurations other than this part are the same as the spin-orbit torque wiring illustrated in FIG. 13.

In FIGS. 3 to 6, 12 and 13, a thickness and a width in a y direction of the spin-orbit torque wiring 40 are illustrated to be constant in a direction of current flow. However, a shape of the spin-orbit torque wiring 40 is not limited to this configuration. For example, the spin-orbit torque wiring 40 may be narrowed in a part superimposed on the magnetoresistance effect element 20 in a plan view from the lamination direction. A current flowing through the spin-orbit torque wiring 40 is concentrated at the narrowed part. In other words, current efficiency supplied to the spin current generation part 41 is increased and generation efficiency of the pure spin current can be increased.

In FIGS. 3 to 6, 12 and 13, a width of the spin current generation part 41 in an x direction (a direction of current flow) is constant in principle in a thickness direction of the spin-orbit torque wiring 40. However, a shape of the spin current generation part 41 is not limited to this configuration. For example, the width of the spin current generation part 41 in the x direction may be configured to decrease in diameter toward the magnetoresistance effect element 20. The spin current generation part 41 has a larger resistance than the low resistance parts 42A and 42B. Therefore, a part of the current flowing through the spin-orbit torque wiring 40 flows along interfaces between the spin current generation part 41 and the low resistance parts 42A and 42B. As a result, a large amount of current can be supplied to the interface between the magnetoresistance effect element 20 and the spin-orbit torque wiring 40, and supply efficiency of the pure spin current to the second ferromagnetic metal layer 23 can be further enhanced.

<Underlayer>

An underlayer (not illustrated) may be formed on a surface of the substrate 10 on the magnetoresistance effect element 20 side. When the underlayer is provided, it is possible to control crystalline properties of each layer including the first ferromagnetic metal layer 21 laminated on the substrate 10 such as crystal orientation, crystal grain size, or the like.

The underlayer preferably has insulation properties. This is to prevent dissipation of a current flowing through the wiring 30 or the like. Various materials can be used for the underlayer.

For example, as one example, a nitride layer having a (001)-oriented NaCl structure and containing at least one element selected from the group consisting of Ti, Zr, Nb, V, Hf, Ta, Mo, W, B, Al, and Ce can be used for the underlayer.

As another example, a layer of a (002)-oriented perovskite-based conductive oxide expressed by a composition formula of ABO₃ can be used for the underlayer. Here, a site A contains at least one element selected from the group consisting of Sr, Ce, Dy, La, K, Ca, Na, Pb, and Ba, and a site B contains at least one element selected from the group consisting of Ti, V, Cr, Mn, Fe, Co, Ni, Ga, Nb, Mo, Ru, Ir, Ta, Ce, and Pb.

As another example, an oxide layer having a (001)-oriented NaCl structure and containing at least one element selected from the group consisting of Mg, Al, and Ce can be used for the underlayer.

As another example, a layer having a (001)-oriented crystal structure or a cubic crystal structure and containing at least one element selected from the group consisting of Al, Cr, Fe, Co, Rh, Pd, Ag, Jr, Pt, Au, Mo, and W can be used for the underlayer.

The underlayer is not limited to one layer, and may have a plurality of layers in which the above-described examples are laminated. By devising a structure of the underlayer, crystalline properties of each layer of the magnetoresistance effect element 20 can be enhanced, and magnetic characteristics can be improved.

<Wiring>

The wiring 30 is electrically connected to the first ferromagnetic metal layer 21 of the magnetoresistance effect element 20. In a case in which magnetization of the second ferromagnetic metal layer 23 is rotated using only an SOT, the wiring 30 is unnecessary. On the other hand, when an STT is utilized in addition to the SOT, it is necessary to cause a current to flow in the lamination direction of the magnetoresistance effect element 20, and thus the wiring 30 is necessary.

The wiring 30 is not particularly limited as long as it is a highly conductive material. For example, aluminum, silver, copper, gold, or the like can be used.

### Second Embodiment

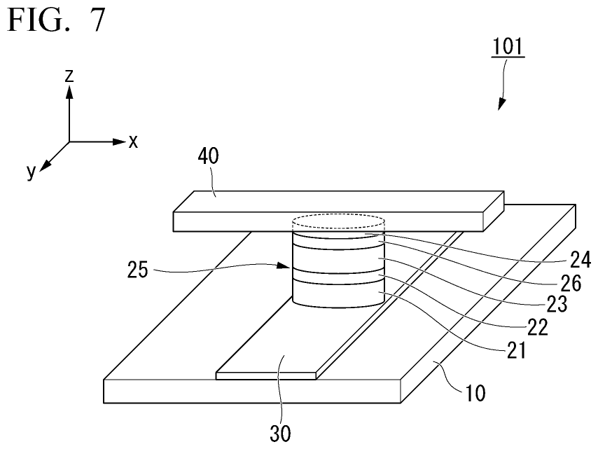

FIG. 7 is a schematic perspective view of a spin current magnetization rotational magnetoresistance effect element according to a second embodiment. A spin current magnetization rotational magnetoresistance effect element 101 according to the second embodiment is different from the spin current magnetization rotational magnetoresistance effect element 100 according to the first embodiment in that a diffusion prevention layer 26 is provided. Other configurations are the same as those of the spin current magnetization rotational magnetoresistance effect element 100 according to the first embodiment, and are denoted by the same reference signs.

The spin current magnetization rotational magnetoresistance effect element 101 according to the second embodiment includes a magnetoresistance effect element 25 and a spin-orbit torque wiring 40. The magnetoresistance effect element 25 includes a diffusion prevention layer 26 between a second ferromagnetic metal layer 23 and a cap layer 24. When the diffusion prevention layer 26 is provided, the spin-orbit torque wiring 40 may be provided on a substrate 10 side.

The diffusion prevention layer 26 is a layer for preventing elements forming the cap layer 24 from diffusing into the second ferromagnetic metal layer 23. As described above, the cap layer 24 is required to have spin conductivity so that a pure spin current supplied from the spin-orbit torque wiring 40 to the second ferromagnetic metal layer 23 is not diffused. However, when only this point is considered, there are cases in which a light element is used as an element forming the cap layer 24 and this element diffuses into the second ferromagnetic metal layer 23.

When a nonmagnetic element diffuses into the second ferromagnetic metal layer 23, a magnetization characteristic of the second ferromagnetic metal layer 23 deteriorates. For example, Mg is an element that can be used for the cap layer 24, but is an element that easily diffuses. By providing the diffusion prevention layer 26 between the cap layer 24 and the second ferromagnetic metal layer 23, diffusion of atoms from the cap layer 24 to the second ferromagnetic metal layer 23 is prevented.

The diffusion prevention layer 26 preferably has at least one selected from a magnetic element and an element having an atomic number equal to or higher than that of yttrium. These elements are heavy and do not easily move. That is, these elements inhibit inflow of diffusing elements. That is, diffusion of the element forming the cap layer 24 into the second ferromagnetic metal layer 23 is inhibited. Further, since these elements are heavy, the element itself forming the diffusion prevention layer 26 cannot easily diffuse into the second ferromagnetic metal layer 23.

Also, a part of the current flowing through the spin-orbit torque wiring 40 is also supplied to the diffusion prevention layer 26. Therefore, for example, when a material constituting the diffusion prevention layer 26 is a nonmagnetic heavy metal, a pure spin current can be generated also in the diffusion prevention layer 26.

A thickness of the diffusion prevention layer 26 is preferably equal to or less than four times an atomic radius (twice the atomic diameter) of the atom constituting the diffusion prevention layer and is more preferably less than twice the atomic radius (equal to the atomic diameter). Here, the thickness of the diffusion prevention layer 26 is a thickness laminated in calculation at the time of manufacturing.

In view of preventing elements from diffusing, the diffusion prevention layer 26 preferably forms a dense layer. However, when a dense layer is formed, a magnetic correlation may also be blocked. Therefore, in order to prevent elements from diffusing while a magnetic correlation is maintained, it is most preferable that elements forming the diffusion prevention layer 26 be present dissipatively in a plane of the layer.

When the thickness in calculation at the time of laminating the diffusion prevention layer 26 is equal to or less than four times the atomic radius of the atom (twice the atomic diameter), a dense layer is not formed and a gap is formed unless precise control is performed. Also, when it is less than twice the atomic radius of the atom (equal to the atomic diameter), it is clear that it is less than a thickness of one atom layer and a dense layer is not formed.

Although the diffusion prevention layer 26 is a very thin layer as described above, it can be analyzed using energy dispersive X-ray spectroscopy (EDS). Further, the thickness of the diffusion prevention layer 26 can also be estimated from a spatial resolution of an apparatus and a half-value width of an obtained peak.

(Method of Manufacturing Spin Current Magnetization Rotational Magnetoresistance Effect Element)

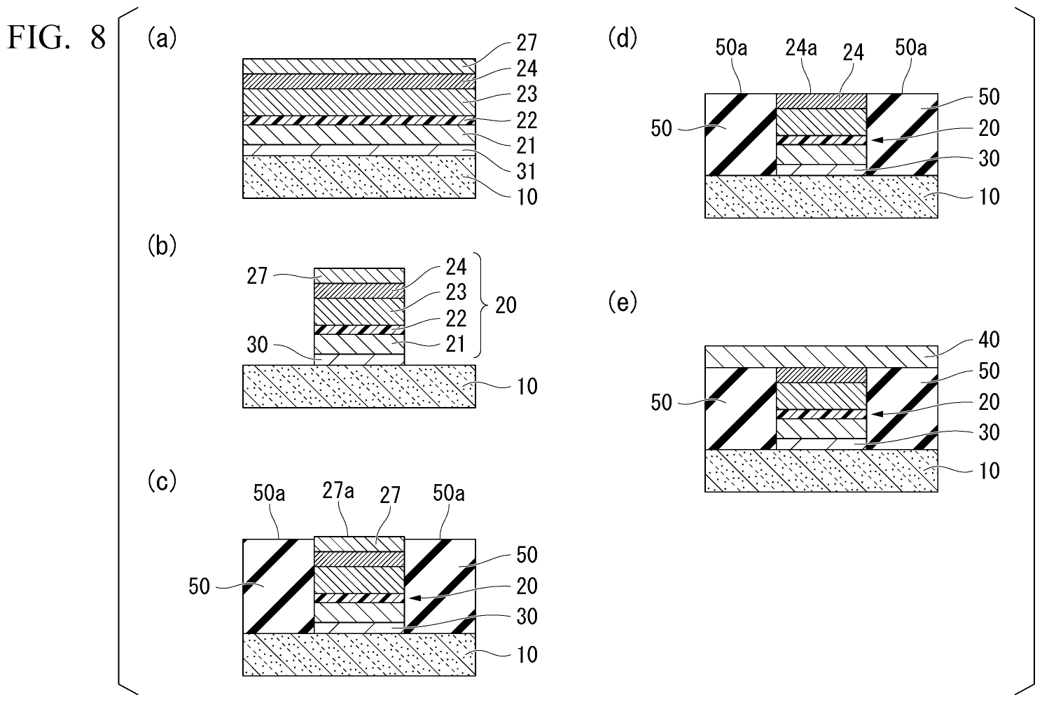

Next, a method of manufacturing a spin current magnetization rotational magnetoresistance effect element according to the present embodiment will be described. FIG. 8 is a view schematically illustrating a manufacturing method of a spin current magnetization rotational magnetoresistance effect element according to the present embodiment.

Hereinafter, a case in which a diffusion prevention layer is not provided will be described as an example. In a case in which a diffusion prevention layer is provided, only a process of laminating the diffusion prevention layer between the second ferromagnetic metal layer 23 and the cap layer 24 is added, and the other processes are the same.

First, as illustrated in FIG. 8 (a), a wiring metal layer 31, a first ferromagnetic metal layer 21, a nonmagnetic layer 22, the second ferromagnetic metal layer 23, the cap layer 24, and a process protection layer 27 are laminated in that order on the substrate 10. When magnetization rotation is performed using only a spin-orbit torque (SOT), the wiring metal layer 31 is unnecessary.

As a method of laminating these, a known method can be used. For example, a sputtering method, an evaporation method, a laser ablation method, a molecular beam epitaxy (MBE) method, or the like can be used. For the nonmagnetic layer 22, a metal thin film may be sputtered and an obtained sputtered metal thin film may be subjected to plasma oxidation or natural oxidation by introducing oxygen.

The process protection layer 27 is a layer that is removed during processing and is a layer that prevents processing damage from being applied to the second ferromagnetic metal layer 23. The process protection layer 27 may be formed using the same material as the cap layer 24 or using a different material.

The process protection layer 27 is preferably not selectively etched during the processing and preferably has mechanical hardness. Therefore, it is preferable to use at least one element selected from the group consisting of Ru, Ta, SiN, W, and Mo as a material constituting the process protection layer 27.

Next, as illustrated in FIG. 8 (b), a resist or the like is provided on the process protection layer 27, a laminate is processed into a predetermined shape, and the magnetoresistance effect element 20 is manufactured. When the wiring 30 and the magnetoresistance effect element 20 are different in shape, the laminate is processed in one direction to obtain the wiring 30, and then the laminate is processed in a direction different from that direction. An ion milling method or a reactive ion etching (RIE) method can be used for processing the laminate.

Then, as illustrated in FIG. 8 (c), in order to protect a side surface of the magnetoresistance effect element 20, an outer circumference of the magnetoresistance effect element 20 is covered with an insulator 50. At this time, an exposed surface 50a of the insulator 50 and an exposed surface 27a of the process protection layer 27 are not necessarily formed at exactly the same position. Even if a film thickness is controlled when the insulator 50 is formed, a slight step may remain between respective surfaces. Further, the exposed surface 27a of the process protection layer 27 is rough due to damage caused when the laminate is processed.

Therefore, as illustrated in FIG. 8 (d), the exposed surface 50a of the insulator 50 and the exposed surface 27a of the process protection layer 27 are polished. As the polishing method, chemical-mechanical polishing (CMP) is preferably used. The process protection layer 27 is removed by polishing, and the cap layer 24 is exposed. The polishing is not necessarily required to stop at an interface between the process protection layer 27 and the cap layer 24, and may be stopped at a stage in which the cap layer 24 is polished to some extent.

By polishing, the exposed surface 50a of the insulator 50 and an exposed surface 24a of the cap layer 24 are on the same plane. The exposed surface 24a of the cap layer 24 is also flat, unlike the exposed surface 27a of the process protection layer 27 before the polishing.

Finally, the spin-orbit torque wiring 40 is laminated on the planarized exposed surface. The spin-orbit torque wiring 40 is processed to extend in a direction intersecting the wiring 30. Thereafter, an exposed surface of the spin-orbit torque wiring 40 is protected with the insulator, and thereby a spin current magnetization rotational magnetoresistance effect element is manufactured.

It is important in this manufacturing method that the exposed surface 24a of the cap layer 24 on which the spin-orbit torque wiring 40 is laminated be planarized. An SOT induced by a pure spin current is greatly affected by an interface effect of a lamination surface. Therefore, the SOT can be efficiently induced by planarizing the exposed surface 24a on which the spin-orbit torque wiring 40 is laminated.

A degree of orientation of magnetization of the second ferromagnetic metal layer 23 is also greatly affected by the lamination interface. For example, in the case of a perpendicular magnetization film, magnetization of the second ferromagnetic metal layer 23 is oriented perpendicular to the lamination interface. If the lamination interface is not flat, the magnetization is oriented to be slightly inclined with respect to the lamination direction. When an orientation direction of magnetization varies, it causes a decrease in magnetoresistance (MR) ratio.

In this manufacturing method, it is also important that an object being polished not be the second ferromagnetic metal layer 23. For example, when only planarization of the lamination surface on which the spin-orbit torque wiring 40 is laminated is considered, it is also conceivable that the second ferromagnetic metal layer 23 is laminated thick and an exposed surface of the second ferromagnetic metal layer 23 is polished. However, when the second ferromagnetic metal layer 23 is formed thick, variations occur in characteristics thereof. In contrast, by providing the process protection layer 27 serving as a layer that is configured to be removed from the beginning, processing such as polishing can be performed without imparting an influence on the second ferromagnetic metal layer 23.

As illustrated in FIGS. 3 to 6, 12 and 13, when the spin-orbit torque wiring 40 is divided into a spin current generation part 41 and low resistance parts 42A and 42B, known processing means such as photolithography or the like can be used.

In this case, it is preferable that the spin current generation part 41 be formed before the low resistance parts 42A and 42B. This is so that the interface between the spin current generation part 41 and the magnetoresistance effect element 20 is not damaged in order to inhibit scattering of the pure spin current supplied from the spin current generation part 41 to the magnetoresistance effect element 20.

(Operation of Spin Current Magnetization Rotational Magnetoresistance Effect Element)

Next, an operation of the spin current magnetization rotational magnetoresistance effect element will be described. The spin current magnetization rotational magnetoresistance effect element outputs magnetization rotation of the second ferromagnetic metal layer 23 as a change in resistance value. Hereinafter, as a method for performing the magnetization rotation of the second ferromagnetic metal layer 23, a method using both of a spin transfer torque (STT) and the SOT, and a method using only the SOT will both be described.

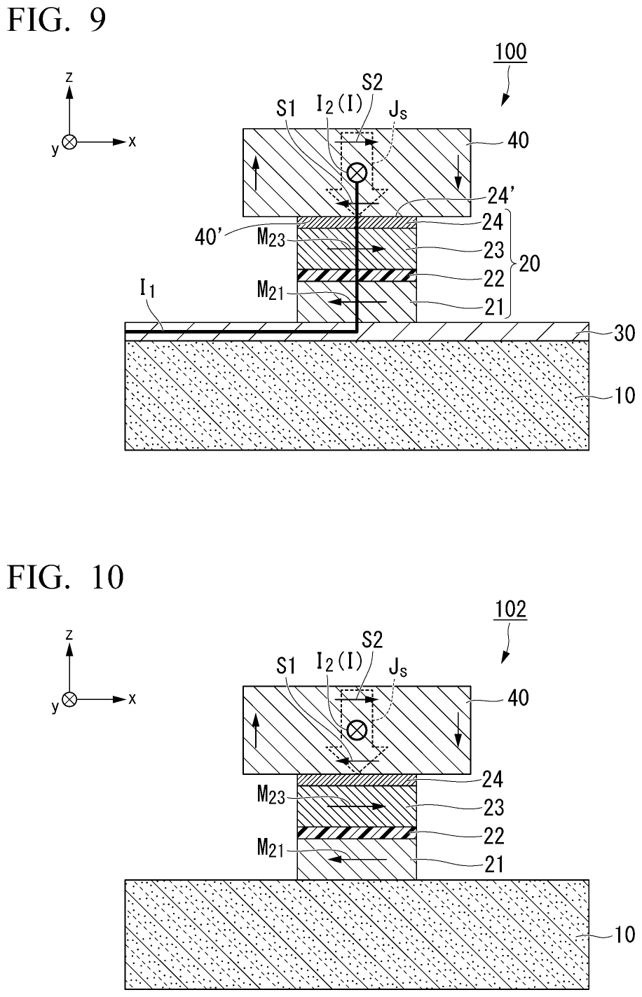

First, a method of performing the magnetization rotation of the second ferromagnetic metal layer 23 using both the STT and the SOT will be described. FIG. 9 is a schematic cross-sectional view of the spin current magnetization rotational magnetoresistance effect element according to the present embodiment taken along an xz plane. FIG. 9 corresponds to a cross-sectional view in the xz plane. An insulator that is unnecessary for understanding the operation of the element is omitted in the illustration.

As illustrated in FIG. 9, there are two kinds of currents in the spin current magnetization rotational magnetoresistance effect element 100. One is a current I₁ (STT inversion current) flowing through the magnetoresistance effect element 20 in a lamination direction and flowing through the spin-orbit torque wiring 40 and the wiring 30. In FIG. 9, the current I₁ flows in the spin-orbit torque wiring 40, the magnetoresistance effect element 20, and the wiring 30 in that order. In this case, electrons flow in the wiring 30, the magnetoresistance effect element 20, and the spin-orbit torque wiring 40 in that order.

Another is a current I₂ (SOT inversion current) flowing in an extending direction of the spin-orbit torque wiring 40. The current I₁ and the current I₂ intersect each other (at a right angle), and a current flowing through the magnetoresistance effect element 20 and a current flowing through the spin-orbit torque wiring 40 are joined or distributed at a part in which the magnetoresistance effect element 20 and the spin-orbit torque wiring 40 are joined (a reference sign 24′ indicates a junction on the side of the magnetoresistance effect element 20 (cap layer 24), and a reference sign 40′ indicates a junction on the side of the spin-orbit torque wiring 40).

When a current I₁ flows, electrons having a spin oriented in a same direction as magnetization of the first ferromagnetic metal layer (fixed layer) 21 pass through the nonmagnetic layer 22 and are supplied to the second ferromagnetic metal layer 23 while the spin direction is maintained. These electrons impart a torque (STT) which causes magnetization M₂₃ of the second ferromagnetic metal layer (free layer) 23 to rotate.

On the other hand, the current I₂ corresponds to the current I illustrated in FIG. 2. That is, when the current I₂ flows, a first spin S1 and a second spin S2 are both bent toward an end part of the spin-orbit torque wiring 40 and produce a pure spin current Jₛ. The pure spin current Jₛ is induced in a direction perpendicular to a direction in which the current I₂ flows. That is, the pure spin current Jₛ is generated in a z-axis direction or an x-axis direction in the drawing. In FIG. 9, only the pure spin current Jₛ in the z-axis direction contributing to a direction of the magnetization of the second ferromagnetic metal layer 23 is illustrated.

The pure spin current Jₛ generated in the spin-orbit torque wiring 40 by flowing the current I₂ on a front side in the drawing diffuses and flows into the second ferromagnetic metal layer 23 via the cap layer 24. The spin that has flowed in affects the magnetization M₂₃ of the second ferromagnetic metal layer 23. That is, in FIG. 9, when a spin oriented in a −x direction flows into the second ferromagnetic metal layer 23, a torque (SOT) for rotating the magnetization M₂₃ of the second ferromagnetic metal layer 23 oriented in a +x direction is applied.

As described above, an SOT effect due to the pure spin current Jₛ generated by the current flowing through a second current path (current I₂) is added to an STT effect caused by the current flowing through a first current path (current I₁), and thereby the magnetization M₂₃ of the second ferromagnetic metal layer 23 is rotated.

In order to rotate the magnetization of the second ferromagnetic metal layer 23 only by the STT effect (that is, a current of only the current I₁ flows), it is necessary to apply a voltage equal to or higher than a predetermined voltage to the magnetoresistance effect element 20. Although a typical driving voltage of a tunnel magnetoresistance (TMR) element is relatively small at several volts or less, the nonmagnetic layer 22 is an extremely thin film of about several nanometers, and insulation breakdown may occur. When a voltage is continued to be applied to the nonmagnetic layer 22, stochastically, a weak part (at which film quality is poor, a film thickness is thin, or the like) of the nonmagnetic layer is destroyed.

In contrast, when the STT effect and the SOT effect are simultaneously used, the voltage applied to the magnetoresistance effect element 20 can be reduced. In addition, current density of the current flowing through the spin-orbit torque wiring 40 can also be reduced. When the voltage applied to the magnetoresistance effect element 20 is reduced, a probability of the insulation breakdown of the nonmagnetic layer 22 decreases. Further, by reducing the current density of the current flowing through the spin-orbit torque wiring 40, energy efficiency can be enhanced.

Next, a method of rotating the magnetization of the second ferromagnetic metal layer 23 using only the SOT will be described. FIG. 10 is a schematic cross-sectional view of the spin current magnetization rotational magnetoresistance effect element according to the present embodiment taken along an xz plane. An insulator that is unnecessary for understanding the operation of the element is removed in the illustration. When only the SOT is used, since the wiring 30 is unnecessary, the spin current magnetization rotational magnetoresistance effect element 102 illustrated in FIG. 10 does not have the wiring 30.

When only the SOT is used, only the above-described current I₂ is used. As described above, the current I₂ causes the pure spin current Jₛ to be generated, and the generated pure spin current Jₛ diffuses and flows into the second ferromagnetic metal layer 23 via the cap layer 24. The spin that has flowed in affects the magnetization M₂₃ of the second ferromagnetic metal layer 23.

That is, in FIG. 10, when a spin oriented in the −x direction flows into the second ferromagnetic metal layer 23, the torque (SOT) for rotating the magnetization M₂₃ of the second ferromagnetic metal layer 23 oriented in the +x direction is applied to rotate the magnetization of the second ferromagnetic metal layer 23.

The current density of the current flowing through the spin-orbit torque wiring 40 is preferably less than 1×10⁷A/cm². When the current density of the current flowing through the spin-orbit torque wiring 40 is excessively large, heat is generated due to the current flowing through the spin-orbit torque wiring 40. The heat reduces stability of the magnetization M₂₃ of the second ferromagnetic metal layer 23.

The deterioration in stability of the magnetization M₂₃ of the second ferromagnetic metal layer 23 increases the likelihood of magnetization rotation due to an unexpected external force. Magnetization rotation leads to rewriting of recorded information. Therefore, from this perspective, it is preferable to reduce the current flowing through the spin-orbit torque wiring 40, and it is preferable to use the method using both the STT and the SOT for magnetization rotation of the second ferromagnetic metal layer 23.

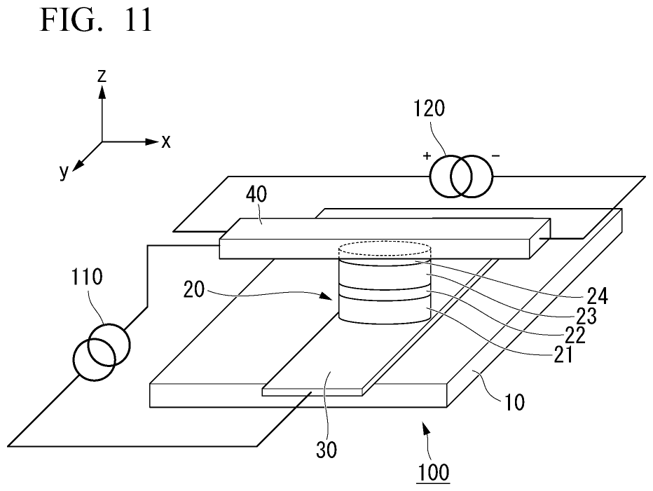

FIG. 11 is a schematic view illustrating the spin current magnetization rotational magnetoresistance effect element according to the present embodiment including a power supply. The spin current magnetization rotational magnetoresistance effect element 100 illustrated in FIG. 11 rotates the magnetization of the second ferromagnetic metal layer 23 using both the STT and the SOT.

A first power supply 110 is connected to the wiring 30 and the spin-orbit torque wiring 40. The first power supply 110 controls a current flowing in the lamination direction of the spin current magnetization rotational magnetoresistance effect element 100. A known power supply can be used for the first power supply 110.

A second power supply 120 is connected to both ends of the spin-orbit torque wiring 40. The second power supply 120 controls a current flowing in a direction perpendicular to the lamination direction of the magnetoresistance effect element 20. That is, the second power supply 120 controls the current flowing through the spin-orbit torque wiring 40. A known power supply can be used for the second power supply 120.

As described above, the current flowing in the lamination direction of the magnetoresistance effect element 20 induces an STT. In contrast, the current flowing through the spin-orbit torque wiring 40 induces an SOT. Both the STT and the SOT contribute to magnetization rotation of the second ferromagnetic metal layer 23.

In this manner, when an amount of the current flowing in the lamination direction of the magnetoresistance effect element 20 and an amount of the current flowing in the direction perpendicular to the lamination direction are controlled by the two power supplies, a contribution ratio of the SOT and the STT contributing to the magnetization rotation can be freely controlled.

For example, when a large current cannot flow through the device, control is performed such that the STT with high energy efficiency for magnetization rotation is mainly used. That is, the amount of current flowing from the first power supply 110 is increased, and the amount of current flowing from the second power supply 120 is reduced.

Also, for example, when it is necessary to manufacture a thin device and a reduction in the thickness of the nonmagnetic layer 22 is inevitable, the current flowing through the nonmagnetic layer 22 is required to be reduced. In this case, the amount of current flowing from the first power supply 110 is reduced, the amount of current flowing from the second power supply 120 is increased, and then the contribution ratio of SOT is increased.

When the magnetization of the second ferromagnetic metal layer 23 is rotated using only the SOT, the wiring 30 and the first power supply 110 in FIG. 11 are unnecessary.

As described above, according to the spin current magnetization rotational magnetoresistance effect element of the present embodiment, even in the magnetoresistance effect element using the SOT with a bottom pin structure, scattering of the spin by the cap layer can be inhibited. Further, by using the process protection layer that is removed during processing, the interface between the cap layer and the spin-orbit torque wiring can be planarized. That is, the pure spin current generated in the spin-orbit torque wiring can be efficiently supplied to the second ferromagnetic metal layer. Further, by providing the diffusion prevention layer, it is possible to prevent elements forming the cap layer from diffusing into the second ferromagnetic metal layer and lowering the MR ratio.

### REFERENCE SIGNS LIST

10 Substrate

20, 25 Magnetoresistance effect element

21 First ferromagnetic metal layer

22 Nonmagnetic layer

23 Second ferromagnetic metal layer

24 Cap layer

27 Process protection layer

30 Wiring

40 Spin-orbit torque wiring

41, 41A, 41B Spin current generation part

42A, 42B, 42C Low resistance part

50 Insulator

I Current

S1 First spin 51

S2 Second spin

100, 101, 102 Spin current magnetization rotational magnetoresistance effect element

What is claimed is:

1. A spin current magnetization rotational magnetoresistance effect element comprising:
a magnetoresistance effect element including a first ferromagnetic metal layer in which a direction of magnetization is fixed, a second ferromagnetic metal layer configured for a direction of magnetization to be changed, and a nonmagnetic layer provided between the first ferromagnetic metal layer and the second ferromagnetic metal layer; and
a spin-orbit torque wiring extending in a first direction intersecting a lamination direction of the magnetoresistance effect element and joined to the second ferromagnetic metal layer,
wherein, the spin-orbit torque wiring contains a pure spin current generation part made of a material that generates a pure spin current and a low resistance part made of a material having electric resistance lower than electrical resistance of the pure spin current generation part,
at least a part of the pure spin current generation part is in contact with the second ferromagnetic metal layer,
the pure spin current generation part is coated with the low resistance part,
the low resistance part has a first convex shape portion projecting in a thickness direction of the low resistance part, and
the first convex shape portion is provided on a position which is superimposed on at least the magnetoresistance effect element in a plan view from the lamination direction of the magnetoresistance effect element.

2. The spin current magnetization rotational magnetoresistance effect element according to claim 1,
wherein the low resistance part has second convex shape portions projecting in the thickness direction of the low resistance part, and
in a plan view from the lamination direction of the magnetoresistance effect element, each of the second convex shape portions is provided on both ends of the first convex shape portion in the first direction.

3. The spin current magnetization rotational magnetoresistance effect element according to claim 1, wherein the spin-orbit torque wiring includes a nonmagnetic metal having an atomic number of 39 or higher having a d electron or an f electron in an outermost shell.

4. The spin current magnetization rotational magnetoresistance effect element according to claim 2, wherein the spin-orbit torque wiring includes a nonmagnetic metal having an atomic number of 39 or higher having a d electron or an f electron in an outermost shell.

5. A magnetic memory comprising a plurality of spin current magnetization rotational magnetoresistance effect elements according to claim 1.
